(19) United States
(12) Patent Application Publication
(10) Pub. No.: US 2009/0226139 A1
(43) Pub. Date: Sep. 10, 2009

(54) Optoelectronic component and optical subassembly for optical communication

(75) Inventor: Rong-Heng Yuang, Hsinchu (TW)

Correspondence Address: CHARLES E. BAXLEY, ESQUIRE, 90 JOHN STREET, SUITE 309, NEW YORK, NY, 10038, US

(73) Assignee: Coretek Opto Corp.

(21) Appl. No.: 12/322,085

(22) Filed: Jan. 28, 2009

(30) Foreign Application Priority Data
Jan. 31, 2008 (CN) 200810006689.3
Feb. 2, 2008 (CN) 200810006840.3
Mar. 3, 2008 (TW) 097107269

(51) Int. Cl. G02B 6/36; H05K 5/06

(52) U.S. Cl. 385/93; 174/50.6

(57) ABSTRACT

An optoelectronic component and an optical sub-assembly for optical communication. The optoelectronic component has a housing and one end formed with an opening. An optoelectronic device is located in the housing and faces the opening. A barrel is combined with the optoelectronic component to form the optical sub-assembly, and the barrel has a lens configuration facing the opening. The lens can enter the housing through the opening to approach the optoelectronic device. Thus, the manufacturing costs of the optoelectronic component and the optical sub-assembly can be lowered, and the optical coupling efficiency of the optical sub-assembly can be enhanced. In addition, a film covers the surface of the optoelectronic device to improve the device reliability.

### BACKGROUND OF THE INVENTION

1. Field of Invention

The invention relates to a component for optical communication, and more particularly to an optical sub-assembly composed of a barrel and an optoelectronic component, wherein the package types of the optoelectronic component include TO-can (TO Open Can) architecture and leadframe architecture, and the type of the barrel may be SC, ST, LC, or their individual pigtail architecture.

2. Related Art

The optical communication is to achieve the signal transmission effect via optical-to-electrical conversion. An optical sub-assembly (OSA) to be connected to an optical fiber connector has to be located at each of a signal transmitting end and a signal receiving end.

U.S. Pat. No. 7,290,946 discloses an optical sub-assembly, which is composed of an optoelectronic component and a barrel combined together, in one of the examples thereof. A housing of the optoelectronic component is formed with an opening so that the effect of the high alignment yield can be achieved. Also, the '946 patent discloses that a glue is coated on or filled inside the optoelectronic component so that the optoelectronic die is isolated from air, or the glue is filled into the space between the optoelectronic die and the optical coupling structure so as to protect the optoelectronic die.

U.S. Pat. Nos. 6,588,949 and 6,283,644 also disclose that a glue is formed into a thick film to cover the optoelectronic die and achieve the effect of protecting the optoelectronic die. However, it is very difficult to prevent the formation of the thick film from having the thickness of several tens of micrometers, at least in general, if the frequently-used conventional glue (e.g., epoxy or silicone) is adopted. As a result, the shape and thickness of the thick film do not have the consistency due to the formation of bubbles and/or surface tension regarding the glue. Thus, the optical properties of the products cannot be well controlled.

### SUMMARY OF THE INVENTION

A housing of an optoelectronic component of the invention, especially a TO-can/leadframe housing, has an opening, and no glass or lens is located on the housing, so the manufacturing cost can be lowered. In addition, an optical coupling structure may penetrate through the opening so as to approach an optoelectronic device/optoelectronic die of the optoelectronic component. The housing of the optoelectronic component may be made by metal, plastic or resin, and the housing has an opening.

Glue or index matching oil is filled into the optoelectronic component of the invention, so the light can be converged with a low diverging angle as travelling through the glue or the index matching oil. In addition, the glue or the index matching oil can protect and/or fix the optoelectronic device or the optoelectronic die. Also, it is also possible to coat a thin film material (e.g., a fluoro-polymer of a polymeric, high volatile dilute material) with a low viscosity coefficient on the surface of the optoelectronic device/optoelectronic die and/or the matching component, e.g., integrated circuit (IC) and active/passive device, without using the above mentioned materials. Thus, it is expected to form a surface protection film against damp heat (high temperature and high humidity) and to reduce the influence of the optical and/or electrical properties. More particularly, regarding to the optoelectronic die with the thin film material coated and located in the housing with/without the opening or directly in a barrel, no matter in which is eventually hermetically sealed or non-hermetically sealed, the property thereof can be improved or the quality thereof can be stabilized.

The optoelectronic die of the invention may be located on an integrated circuit, and the combination of the optoelectronic die and the integrated circuit may be located on a submount. Thus, the area occupied by each assembly can be reduced so that the spatial availability can be optimized. In addition, the size of the optoelectronic component can be reduced and the high-frequency performance can be enhanced. Furthermore, the submount can also be removed so that the spatial availability can be further improved and the size of the optoelectronic component can be much more reduced.

In the optoelectronic component of the invention, it is assumed that its housing has an opening and is used in conjunction with the optoelectronic device without the submount, and then the thin film material with a low viscosity coefficient covers the optoelectronic die and/or the matching component, and finally combined with the barrel. In this case, the optoelectronic die or the matching component may have the improved or stabilized quality due to the protection of the low-viscosity material regardless of whether the chamber of the optoelectronic component is hermetically sealed with the barrel. The opening thereof may further let the lens on the first surface of the barrel go inside to approach the optoelectronic die so that the submount may be omitted, the cost or the product size can be further reduced.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative in the present invention.

FIG. 1a is a schematic illustration showing a structure of an optoelectronic component with the TO-can architecture with the opening according to the invention.

FIG. 1b is a schematic illustration showing the optoelectronic component with the TO-can architecture but without the housing according to the invention.

FIG. 2 is a schematic illustration showing the optoelectronic component with the leadframe architecture according to the invention.

FIG. 3 is a schematic illustration showing another optoelectronic component with another leadframe architecture according to the invention.

FIG. 4a is a schematic illustration showing a structure, in which an optoelectronic die of the optoelectronic device of the invention is located on a submount.

FIG. 4b is a schematic illustration showing another structure, in which the optoelectronic die of the optoelectronic device of the invention is located on the submount.

FIG. 5a is a schematic illustration showing a structure, in which the film of the invention covers the surface of the optoelectronic device.

FIG. 5b is another schematic illustration showing another structure, in which the film of the invention covers the surface of the optoelectronic device.

FIG. 6a is a schematic illustration showing a structure, in which an optoelectronic die of the optoelectronic device of the invention is located on a matching component.

FIG. 6b is another schematic illustration showing another structure, in which the optoelectronic die of the optoelectronic device of the invention is located on the matching component and includes a submount.

FIG. 7a is a schematic illustration showing a structure, in which the film of the invention covers the surface of the optoelectronic device.

FIG. 7b is another structure schematic illustration showing another structure, in which the film of the invention covers the surface of the optoelectronic device and includes a submount.

FIG. 8a is a schematic illustration showing the structure of the optoelectronic component of the invention without a housing, wherein the optoelectronic die is located on the matching component.

FIG. 8b is a schematic illustration showing the structure of the optoelectronic component of the invention with the housing, wherein the optoelectronic die is located on the matching component.

FIG. 8c is a schematic illustration showing the structure of the optoelectronic component of the invention, wherein a spherical lens is located on the housing and the optoelectronic die is located on the matching component.

FIG. 8d is a schematic illustration showing the structure of the optoelectronic component of the invention, wherein a piece of flat window is located on the housing and the optoelectronic die is located on the matching component.

FIG. 8e is a schematic illustration showing the structure of the optoelectronic component of the invention, wherein a lens structure is located on the housing and the optoelectronic die is located on the matching component.

FIG. 9a is a schematic illustration showing the structure of the optoelectronic component of the leadframe architecture of the invention without a housing, wherein the optoelectronic die is located on the matching component.

FIG. 9b is a schematic illustration showing the structure of the optoelectronic component of the leadframe architecture of the invention with the housing, wherein the optoelectronic die is located on the matching component.

FIG. 9c is a schematic illustration showing the structure of the optoelectronic component of the leadframe architecture of the invention with a housing of a covering structure, wherein the optoelectronic die is located on the matching component.

FIG. 9d is a schematic illustration showing the structure of the optoelectronic component of the leadframe architecture of the invention, wherein the housing is formed with a lens structure and the optoelectronic die is located on the matching component.

FIG. 10a is a schematic illustration showing that the same side of the optoelectronic die of the invention has two electrodes combined with the matching component.

FIG. 10b is a schematic illustration showing that the same side of the optoelectronic die of the invention has two electrodes combined with the matching component.

FIG. 10c is a schematic illustration showing that the optoelectronic die of the invention is combined with the matching component by the flip chip technique.

FIG. 10d is a schematic illustration showing that the optoelectronic die of the invention is combined with the matching component by the flip chip technique.

FIG. 10e is a schematic illustration showing that the opposite sides of the optoelectronic die of the invention have electrodes combined with the matching component.

FIG. 10f is a schematic illustration showing that the opposite sides of the optoelectronic die of the invention have electrodes combined with the matching component.

FIG. 10g is a schematic illustration showing the electrical connection structure formed by a branch capacitor of the invention and the optoelectronic die.

FIG. 11a is a schematic illustration showing a structure, in which the optoelectronic die of the invention is located on the header.

FIG. 11b is a schematic illustration showing a structure, in which the optoelectronic die of the invention is located on the header, and the film covers the surface of the optoelectronic die.

FIG. 11c is a schematic illustration showing a P-side down assembly of the optoelectronic component of the invention.

FIG. 12 is a schematic illustration showing a P-side up assembly of the optoelectronic component of the invention.

FIG. 13a is a schematically assembled view showing a P-side up assembly of the optoelectronic component of the invention, wherein a transimpedance amplifier is provided.

FIG. 13b is a schematically assembled view showing a branch capacitor located in the optoelectronic component of the invention.

FIG. 13c is a schematically assembled view showing the optoelectronic component of the invention, in which a chip-type transimpedance amplifier and a postamplifier are provided.

FIG. 14a is a schematically assembled view showing the optoelectronic component of the invention, in which a chip-type driver IC is provided.

FIG. 14b is a schematically assembled view showing that two optoelectronic dies and a chip-type driver IC are located on the header of the invention.

FIG. 15a is a schematic illustration showing a structure of the optoelectronic component of the invention without a housing, wherein the optoelectronic die is located on the header.

FIG. 15b is a schematic illustration showing a structure of the optoelectronic component of the invention with a housing, wherein the optoelectronic die is located on the header.

FIG. 15c is a schematic illustration showing a structure of the optoelectronic component of the invention, wherein a spherical lens is located on the housing and the optoelectronic die is located on the header.

FIG. 15d is a schematic illustration showing a structure of the optoelectronic component of the invention, wherein a piece of flat window is located on the housing and an optoelectronic die is located on the header.

FIG. 15e is a schematic illustration showing a structure of the optoelectronic component of the invention, wherein a lens structure is located on the housing and the optoelectronic die is located on the header.

FIG. 16a is a schematic illustration showing a structure of the optoelectronic component of the leadframe architecture of the invention without a housing, wherein the optoelectronic die is located on the header.

FIG. 16b is a schematic illustration showing a structure of the optoelectronic component of the leadframe architecture of the invention with a housing and an opening, wherein the optoelectronic die is located on the header.

FIG. 16c is a schematic illustration showing a structure of the optoelectronic component of the leadframe architecture of the invention with the housing of the covering structure, wherein the optoelectronic die is located on the header.

FIG. 16d is a schematic illustration showing a structure of the optoelectronic component of the leadframe architecture of the invention, wherein the housing is formed with a lens structure and the optoelectronic die is located on the header.

FIG. 17a is a schematic illustration showing another structure showing another optoelectronic component with another leadframe of the invention without a housing.

FIG. 17b is a schematic illustration showing another structure showing another optoelectronic component with another leadframe of the invention with the housing.

FIGS. 18a to 18d are schematic illustrations showing four structures of barrels of the invention, which are frequently seen.

FIG. 19a is a schematic illustration showing a structure, in which the lens of the optical sub-assembly of the invention extends to approach the optoelectronic device.

FIG. 19b is a schematic illustration showing a structure, in which the lens of the optical sub-assembly of the invention extends to approach the optoelectronic device, wherein the film covers the surface of the optoelectronic device.

FIG. 19c is a schematic illustration showing a structure, in which the lens of the optical sub-assembly of the invention extends to approach the optoelectronic device, wherein the film covers the surface of the optoelectronic device and the optoelectronic die is fixed on the header;

FIG. 20a is a schematic illustration showing a structure, in which a index matching oil is filled, according to the invention.

FIG. 20b is a schematic illustration showing another structure, in which the index matching oil is filled, according to the invention.

FIG. 20c is a schematic illustration showing a structure, in which a glue is filled, according to the invention.

FIG. 20d is a schematic illustration showing another structure, in which the glue is filled, according to the invention.

FIG. 20e is a schematic illustration showing still another structure, in which the glue is filled, according to the invention.

FIG. 20f is a schematic illustration showing yet still another structure, in which the glue is filled, according to the invention.

FIG. 20g is a schematic illustration showing a structure, in which the optoelectronic device coated with the glue, according to the invention.

### DETAILED DESCRIPTION OF THE INVENTION

The present invention will be apparent from the following detailed description, which proceeds with reference to the accompanying drawings, wherein the same references relate to the same elements.

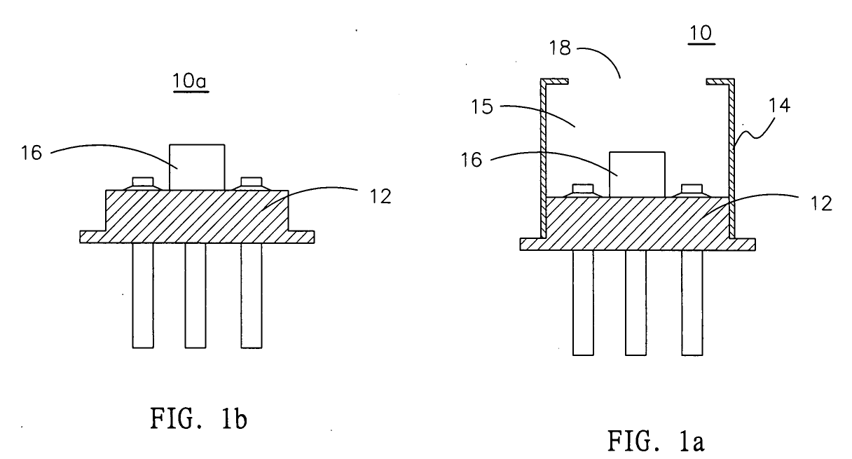

FIG. 1a shows an optoelectronic component 10 with the TO-can architecture. Referring to FIG. 1a, the optoelectronic component 10 has a metal header 12 and a metal housing 14, both can be combined into a single unit. A housing chamber 15 is formed inside the housing 14. An optoelectronic device 16 is mounted in the housing 14 and fixed to the header 12.

More particularly, one end of the housing 14 has an opening 18. The opening 18 is communicated with the housing chamber 15 and located opposite the optoelectronic device 16.

FIG. 1b shows an optoelectronic component 10a, in which no housing is disposed on the header 12, so the optoelectronic device 16 has an open periphery. In other words, the optoelectronic device 16 emits or receives light, which is similar to that of FIG. 1a.

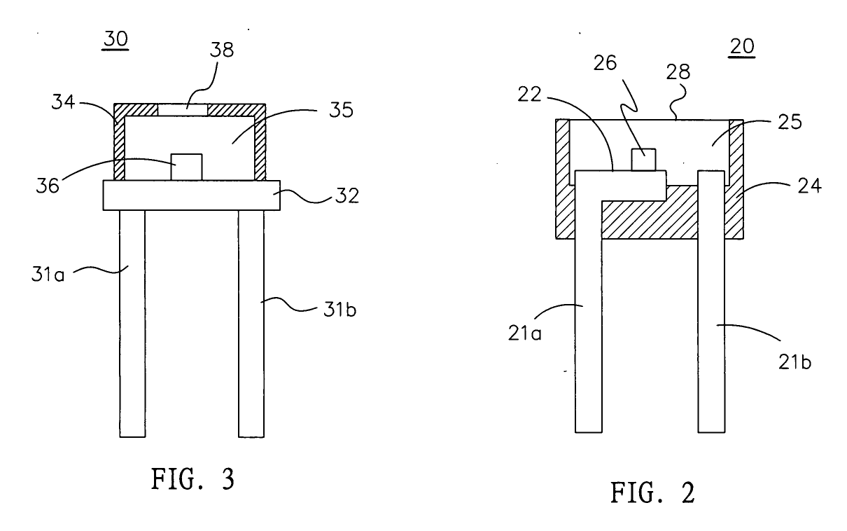

FIG. 2 shows an optoelectronic component 20 with a leadframe architecture. The optoelectronic component 20 has a plurality of metal leads (only two metal leads 21a and 21b are depicted in FIG. 2), and one end of the frame 21a serves as a header 22. A resin housing 24 is combined with one end of each of the metal frames 21a and 21b. An optoelectronic device 26 is located in the housing 24 and fixed to the header 22.

More particularly, an opening 28 is formed at one end of the housing 24 and located opposite the optoelectronic device 26. Because the depth direction of the opening 28 directs to the optoelectronic device 26, a housing chamber 25 is formed inside the resin housing 24.

FIG. 3 shows another optoelectronic component 30 with a leadframe architecture. Unlike the previous embodiment, a header 32 is made of a plastic, resin or metal material and combined with one end of each of metal leads 31a and 31b. An optoelectronic device 36 is located on the header 32.

In addition, a plastic or resin housing 34 is combined with the header 32. An opening 38 is formed at one end of the housing 34, and a housing chamber 35 communicating with the opening 38 is formed inside the housing 34. During packaging, the optoelectronic device 36 is located inside the housing 34 and fixed to the header 32, and opposite the opening 38.

The housings 14, 24 and 34 of the optoelectronic components 10, 20 and 30 according to the embodiments respectively have openings 18, 28 and 38 located opposite the optoelectronic devices 16, 26 and 36.

Each of the optoelectronic devices 16, 26 and 36 may sometimes include a submount, at least one optoelectronic die and with at least one or without any matching component.

Taking the optoelectronic device 16 as an example, the arrangement of each assembly includes various types as follows. The arrangements for other optoelectronic devices 26 and 36 may be obtained analogically.

### First Type: Optoelectronic Die is Located on Submount

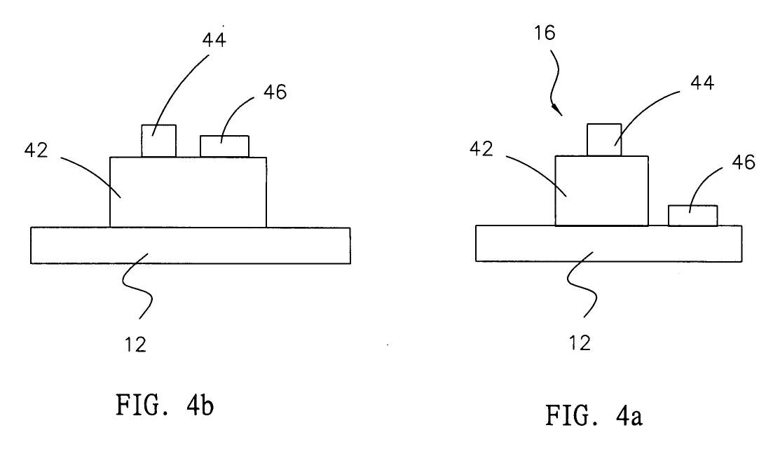

FIG. 4a shows a submount 42 of the optoelectronic device 16 mounted on the header 12. An optoelectronic die 44 is fixed to the submount 42, and a matching component 46 is mounted on the header 12. FIG. 4b shows that the optoelectronic die 44 and the matching component 46 are mounted on the submount 42, and that the submount 42 is disposed on the header 12.

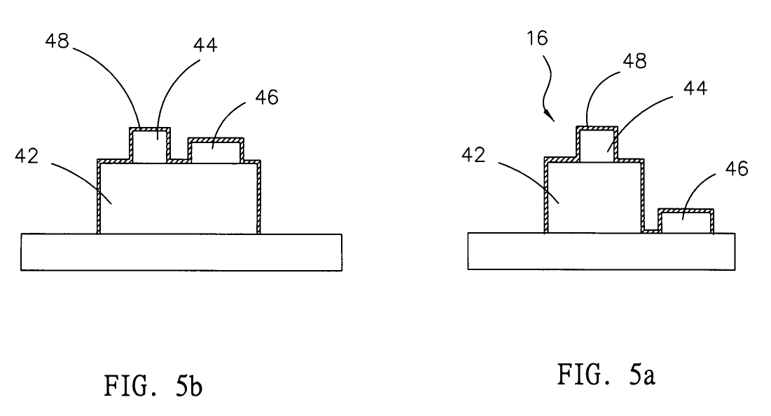

FIGS. 5a and 5b shows an extended structure, which further has a thin film 48 covering the surface of the optoelectronic device 16, or the surfaces of the optoelectronic die 44 and the matching component 46, or the surfaces of the optoelectronic die 44, the matching component 46 and the submount 42. The thin film 48 may also only cover the surface or a portion of the surface of the optoelectronic die and/or the matching component. More particularly, the thin film 48 is covered on an active region of the optoelectronic die 44.

### Second Type: Optoelectronic Die is Located on Matching Component

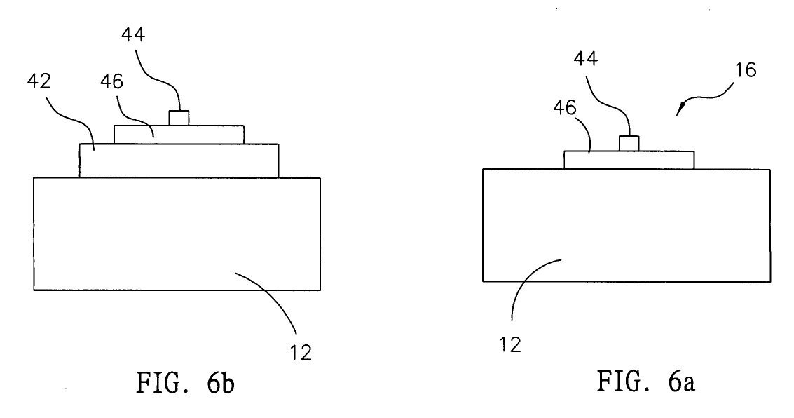

FIG. 6a shows that the optoelectronic device 16 is an optoelectronic die 44 stacked on a matching component 46, and the combination thereof is disposed on the header 12. In the architecture, the matching component 46 may be served as a lower fixing component for the optoelectronic die 44, and may adjust the position (height) of the optoelectronic die 44. FIG. 6b shows that the combination of the optoelectronic die 44 and the matching component 46 is located on a submount 42, which is located on the header 12. Consequently, the submount 42 and the matching component 46 may cooperate with each other to so that the position (height) of the optoelectronic die 44 can be adjusted.

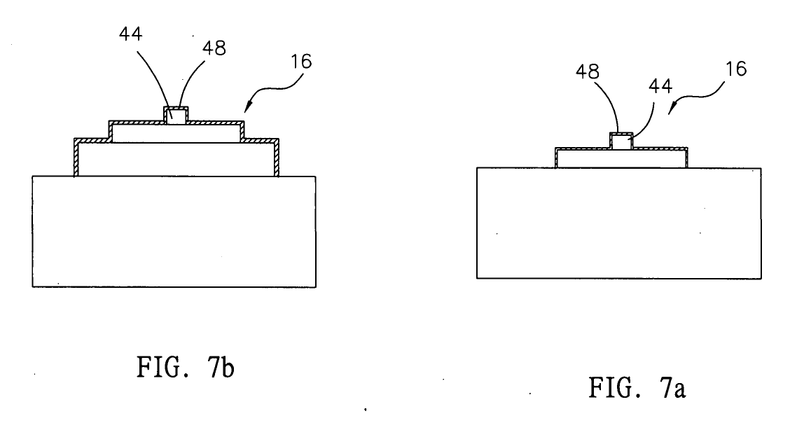

FIGS. 7a and 7b show the extended structure, which further has a film 48 covering the partial or whole surface of the optoelectronic device 16. For example, the film 48 only covers the surface of the optoelectronic die 44.

Taking the optoelectronic device with the TO-CAN architecture but without the film as an example, the assembled architecture of the optoelectronic device and the housing will be described in the following.

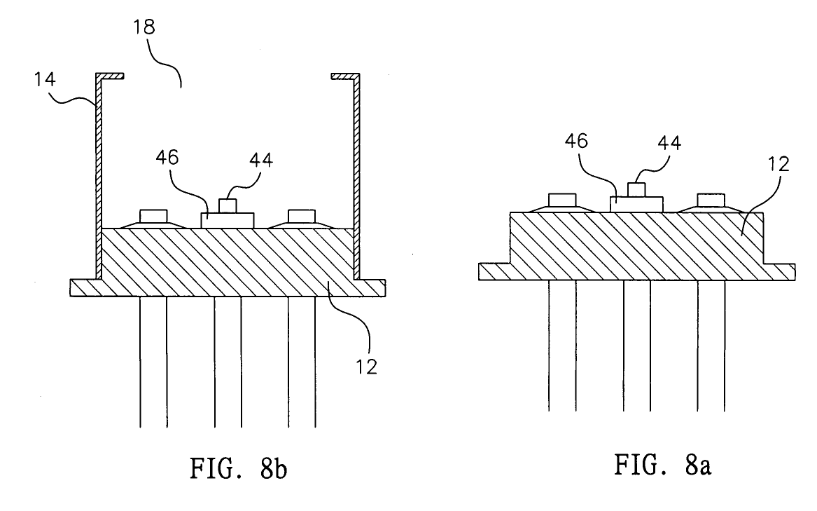

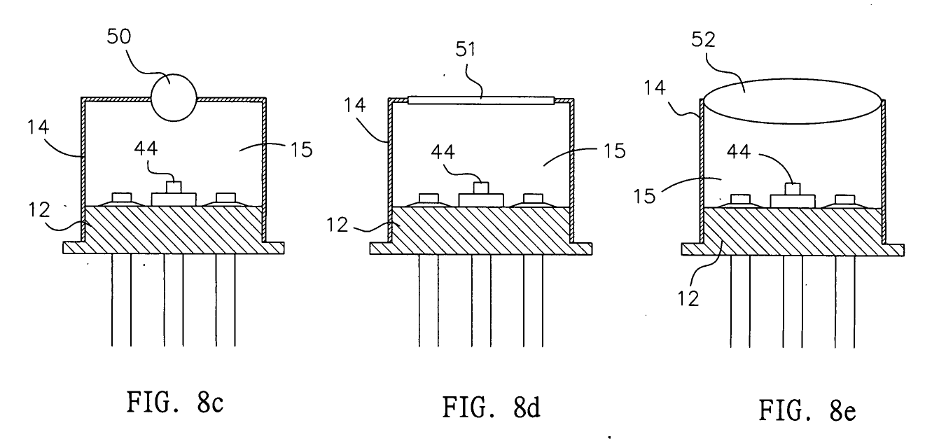

FIG. 8a shows that no housing is located around the header 12. So, an open space is formed around of the optoelectronic die 44 and the matching component 46.

FIG. 8b shows that a metal housing 14 is located on the header 12, wherein an opening 18 is particularly formed at one end of the housing 14 and located opposite the optoelectronic die 44. The combination of the optoelectronic die 44 and the matching component 46 is located on the header 12.

FIG. 8c shows that a metal housing 14 is located on the header 12, wherein a spherical lens 50 is particularly located at one end of the housing 14 and opposite the optoelectronic die 44.

FIG. 8d shows that a metal housing 14 is located on the header 12, wherein a piece of flat window 51 is particularly located at one end of the housing 14 and opposite the optoelectronic die 44.

FIG. 8e shows that a metal housing 14 is located on the header 12, wherein a lens structure 52 is particularly located at one end of the housing 14 and opposite the optoelectronic die 44. The lens can be an aspherical lens or any kind of light-converging device.

The header 12 is a metal header. In addition, the optoelectronic device 16 with the thin film 48 may be used in each embodiment of the invention.

Taking the optoelectronic device with the leadframe architecture but without the film as an example, the combined architecture of the optoelectronic device and the housing will be described in the following.

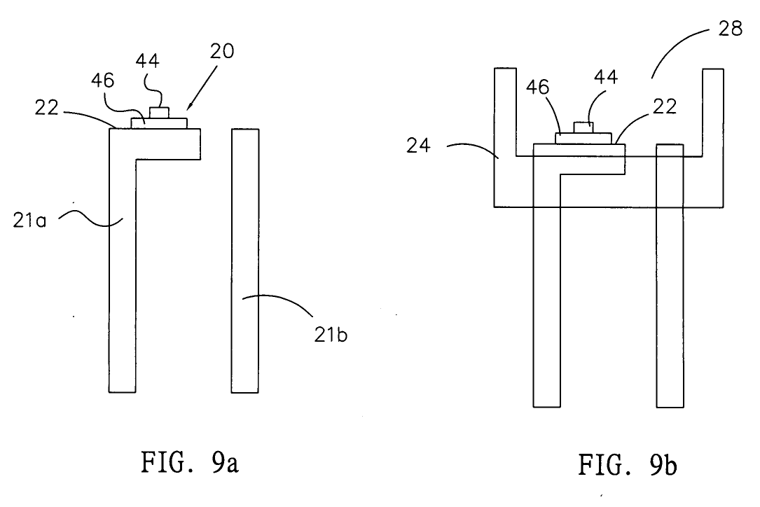

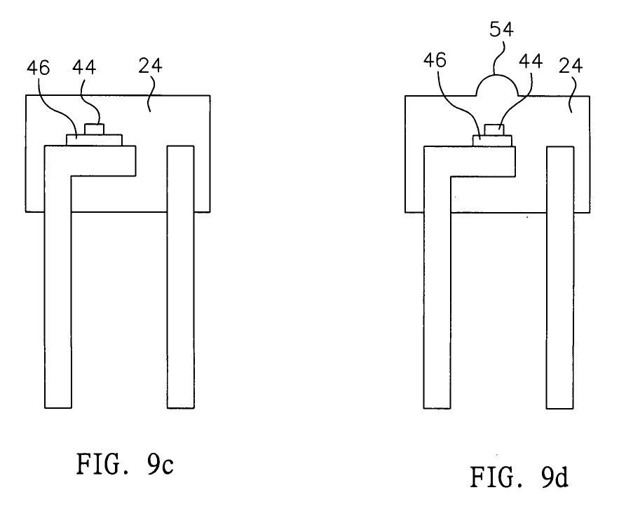

FIG. 9a shows that an optoelectronic component 26 has a plurality of metal leads (only two metal leads 21a and 21b are depicted in the drawing). An end portion of the lead 21a serves as the header 22. The stack of the matching component 46 and the optoelectronic die 44 are disposed on the header 22. The leadframe has no housing or external package body, so an open space is formed around the optoelectronic die 44.

FIG. 9b shows that the leadframe structure is combined with a housing 24, and an opening 28 is formed at one end of the housing 24. The stack of the matching component 46 and the optoelectronic die 44 is located on the header 22, and the optoelectronic die 44 is located opposite the opening 28.

FIG. 9c shows that the leadframe structure is combined with a housing 24, which completely covers the optoelectronic die 44 and the matching component 46. FIG. 9d shows that a housing 24 completely covers the optoelectronic die 44 and a matching component 46, wherein a lens structure 54 is formed at one end of the surface of the housing 24 and located opposite the optoelectronic die 44. The lens could be an epoxy-lens, or an injection-molding-lens.

FIG. 3 shows a leadframe structure having the metal or plastic header 32. Thus, the stack of the optoelectronic die 44 and the matching component 46 may be located on the header 32. Furthermore, during the process of forming the header 32, a housing 34 may be injection-molded to combine with the header 32. Then, the optoelectronic die 44 and the matching component 46 are located in the housing 34 during the packaging process.

FIGS. 6a, 6b, 7a, 7b 8a to 8e and 9a to 9d show that the architecture of the stack of the optoelectronic die 44 and the matching component 46 may be adapted to various kinds of TO-can components and leadframe components. In addition, the combined architecture of the optoelectronic device 16 and the housing 14 with the film 48 is the same as that of the above-mentioned embodiment. Also, FIGS. 8c to 8e respectively show that the light rays may penetrate through the spherical lens 50, the flat window 51 and the lens structure 52 on the housing 14, so these assemblies may be referred to as optical element. However, the optical elements are not limited thereto. Also, the housing chamber 15 is preferably in a hermetically-sealed status via the optoelectronic element is sealed in the housing 14. The inner atmosphere may be nitrogen. The standard leakage tests include gross and fine leakage tests. The typical sealed condition is defined under fine leakage test by the leak rate lower than 5×10⁻⁵ atm-cc/sec. However, the currently preferred standard can be lower than 5×10⁻⁸ atm-cc/sec.

The electrical characteristic of the optoelectronic die 44 stacked on the matching component 46 will be further described in the following.

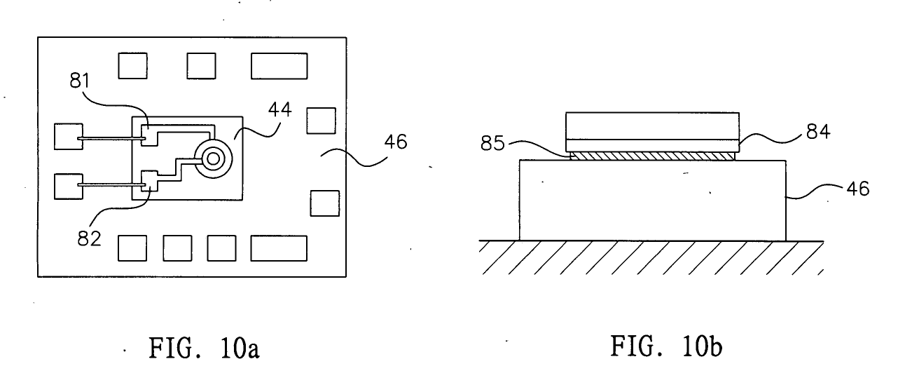

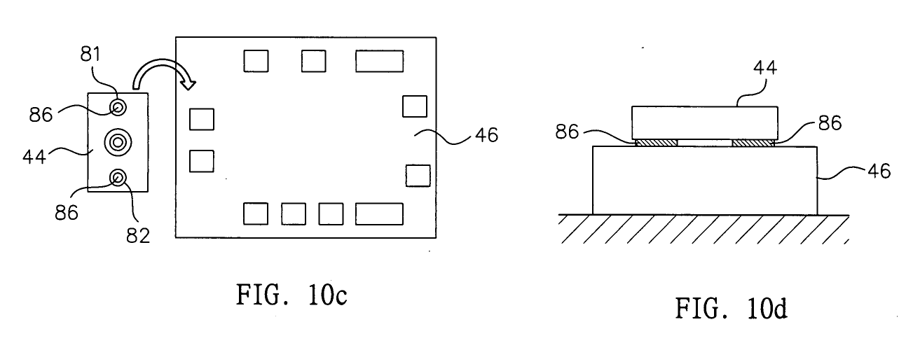

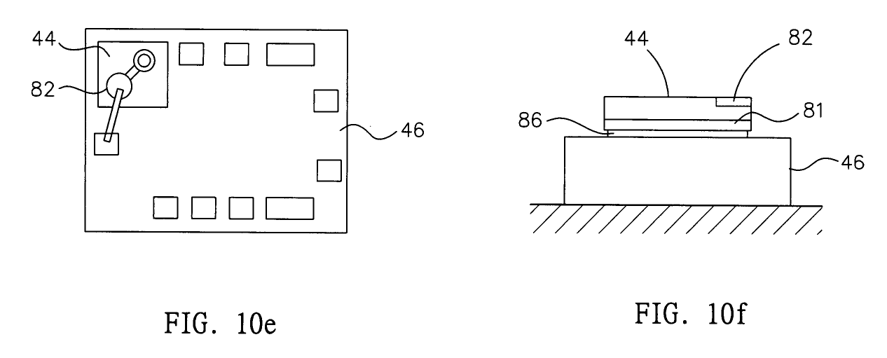

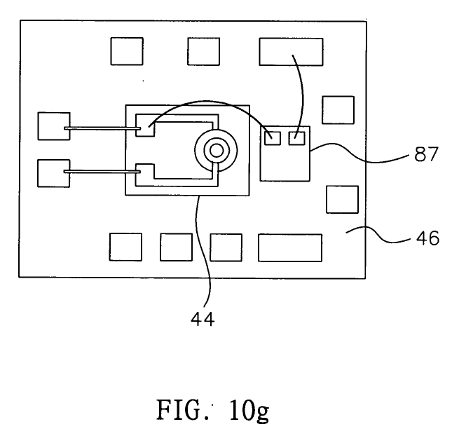

FIGS. 10a and 10b show that the optoelectronic die 44 is stacked on the matching component 46. One side of the optoelectronic die 44 has two electrodes (bonding pad regions) 81 and 82. The other side of the optoelectronic die 44 has a substrate 84, such as a semi-insulating or insulating layer, adhered to the matching component 46 via an substantially insulative adhesive 85. Thus, the electrodes (bonding pad regions) 81 and 82 are located in a direction away from the surface of the matching component 46.

FIGS. 10c and 10d show that the optoelectronic die 44 and the matching component 46 are combined by the flip chip technique. Two electrodes 81 and 82 of the optoelectronic die 44 are located on the same side, and are adhered and electrically connected to the electrodes on the matching component 46 by a conductive adhesive 86 or a solder.

FIGS. 10e and 10f show the optoelectronic die 44 having the vertical architecture. That is, two electrodes 81 and 82 are respectively located on two opposite sides. The electrode 81 is adhered to the matching component 46 via a conductive paste (silver paste) 86. The electrode (bonding pad region) 82 is located in a direction away from the surface of the matching component 46, and a wire is connected to the electrode 82 so that the optoelectronic die 44 is electrically connected to the matching component 46.

In fact, the optoelectronic die 44 only occupies a portion of the area of the matching component 46. Thus, FIG. 10g shows a passive device 87, such as a capacitor, a resistor, an inductor or any combination thereof, which may be located on the matching component 46. The electrodes of the passive device 87 may be formed on the same side surface, or opposite sides. For example, the capacitor may be a capacitor having the SMD architecture, or may be a chip capacitor. In addition to the condition, in which the passive device 87 is located on the matching component 46, an active device, such as a Zener diode, may also be located on the matching component 46.

In detail, the stack of the optoelectronic die 44 and the matching component 46 may increase or optimize the spatial availability of the optoelectronic component so that the size reduction of the optoelectronic component become more practical.

### Third Type: Optoelectronic Die is Fixed to Header

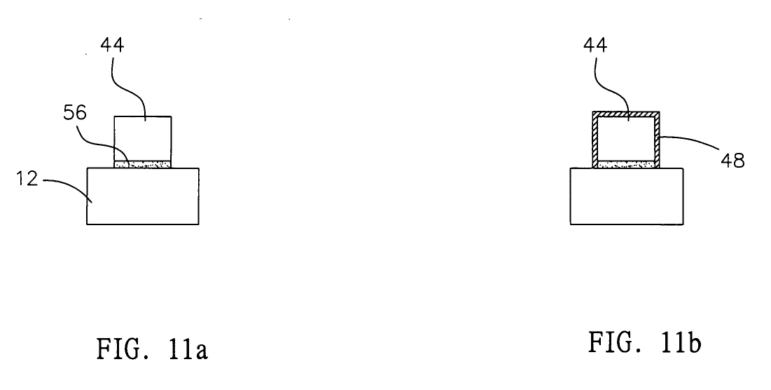

FIG. 11a shows that the optoelectronic die 44 is fixed to the surface of the metal header 12 by an adhesive layer 56. Obviously, this embodiment has no submount. FIG. 11b shows that a thin film 48 covers the surface of the optoelectronic die 44. This embodiment has no submount.

FIG. 11c shows that the optoelectronic die 44 is a diode. The optoelectronic die 44 has a P-type metal layer 61, a semiconductor layer 62, a substrate 63 and an N-type metal layer 64, wherein the semiconductor layer 62 has an active region, and the substrate 63 is an N-type substrate. The optoelectronic die 44 having the P-type substrate may also be analogized.

The combination of the optoelectronic die 44 and the header 12 is performed by moving the P-type metal layer 61 toward the header 12 with the adhesive layer 56 interposed therebetween. The material of the adhesive layer 56 may be an electroconductive adhesive, such as a metal-filled adhesive, a solder (e.g., AuSn) or a solder paste (e.g. SAC), or a mixture of the electroplated metals with tin and the flux.

The above-mentioned adhesive material can be combined with the header 12 without the submount structure, so the adhesive layer 56 can combine the P-type metal layer 61 with the metal header 12. Even if the adhesive layer 56 overflows, the adhesive layer cannot be adhered to the semiconductor layer 62 after reflow. So, it is possible to prevent the optoelectronic die 44 from becoming device short-circuit. In addition, the P-type metal layer 61 is electrically connected to an electrode pin 65 through the adhesive layer 56, and the N-type metal layer 64 is electrically connected to another electrode pin 66 through a wire 67.

No submount is used in this embodiment, so the cost can be reduced, the size can be reduced, and the high frequency property of the component can further be improved. The package yield can be enhanced by selecting the suitable material of the adhesive layer 56. In addition, in the optoelectronic die with the N type substrate, the adopted P-side down packaging structure can transfer the heat, generated by the optoelectronic component, to the header 12 through the adhesive layer 56 and the P-type metal layer 61 more easily so that the heat dissipation of the optoelectronic component can be further improved.

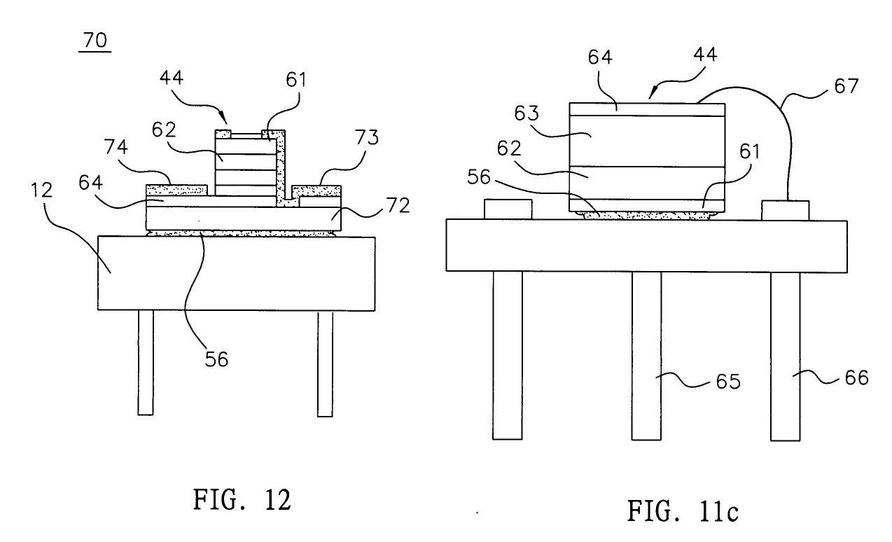

FIG. 12 shows that the optoelectronic die 44 has a semi-insulating or insulating substrate 72 with the high impedance (>10⁷ ohm-cm). In addition, it includes a P-type metal layer 61, an N-type metal layer 64 and a semiconductor layer 62. It is to be noted that a first electrode 73 and a second electrode 74 are formed on the semi-insulating or insulating layer 72 and located on the same surface.

The optoelectronic die 44 has the P-side up package type. The semi-insulating or insulating layer 72 corresponds to the header 12, and the material of the adhesive layer 56 is an electroconductive adhesive or an insulative adhesive. Although the optoelectronic die 44 is directly adhered to the surface of the header 12 by the adhesive layer 56, no short-circuited condition is caused because the semi-insulating or insulating layer 72 is not electrically connected to the metal header 12. The above-mentioned architecture may serve as a photo detector 70.

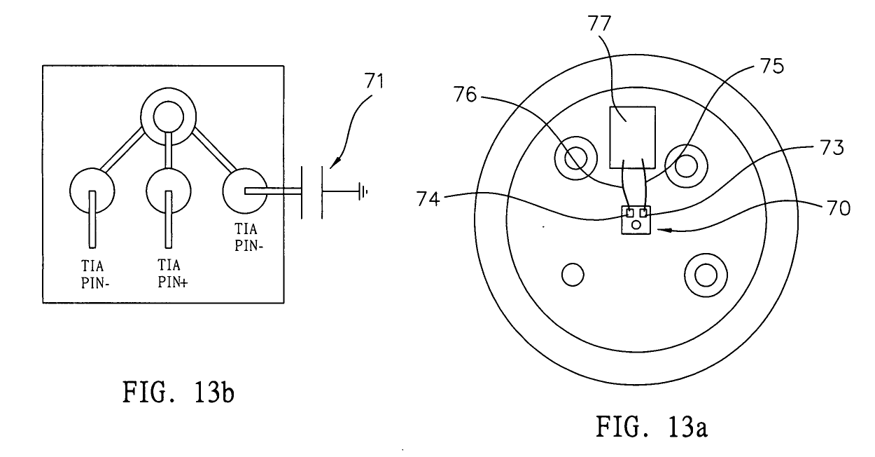

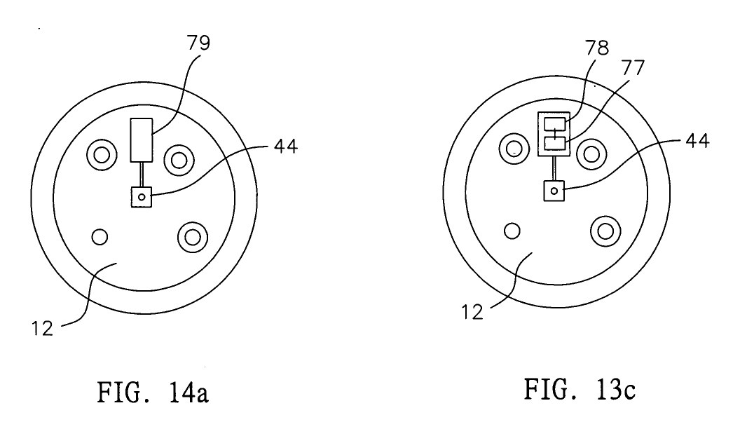

FIG. 13a shows that the wire bonding regions of two electrodes 73 and 74 of the photo detector 70 are exposed and located on the surface of the component. So, the user can connect the two wires 75 and 76 respectively to the two electrodes 73 and 74 and a transimpedance amplifier 77. The transimpedance amplifier 77 converts photocurrent signal into voltage signal, amplifies the amplitude of the voltage signal and outputs the amplified signal.

FIG. 13b shows that a bypass capacitor 71 may be provided to filter out the high-frequency noise in this embodiment. This design can greatly reduce the capacitance of the bonding pads. Thus, many bonding pads may be provided, or the area of the bonding pad may be enlarged to allow many wire bonding points. The bonding pads are to be connected to PIN+ and PIN− of the TIA pins.

FIG. 13c shows that a transimpedance amplifier 77 and a postamplifier (Postamp/Limiting Amplifier) 78 may be combined together to form a single chip-type component, which can be electrically connected to the optoelectronic die 44. The function of the postamplifier 78 is to amplify the differential voltage signal from the transimpedance amplifier 77, into an output signal with a stable amplitude. Because the transimpedance amplifier 77 and the postamplifier 78 are combined together to form a single chip-type component, it can be electrically connected to the optoelectronic die 44 conveniently. In addition, no submount is used in this embodiment, so the header 12 has the enough space for the mounting of the chip component. Consequently, the implementation of the smaller package structure, containing the header with the smaller area, is indirectly induced, and the requirement of the shorter wire is caused so that the high frequency performance of the component is enhanced.

If the optoelectronic die 44 is a light-emitting diode (LED) or a laser diode (LD), a driving and control circuit has to be provided to control the light emitting type.

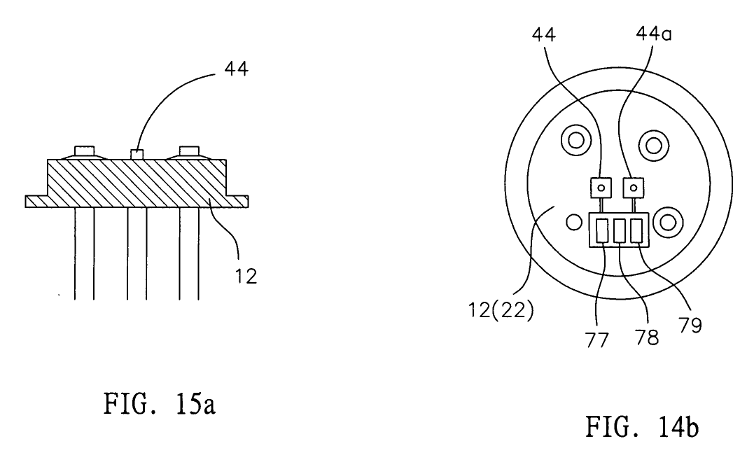

FIG. 14a shows a chip-type driver integrated circuit (Driver IC) 79, which includes a driving and control circuit and is electrically connected to the optoelectronic die (LED or LD) 44. In this embodiment, the size of the circuit board can be reduced, and the header 12 further can provide the enough space for the mounting of the driver IC 79 because no submount is present.

FIG. 14b shows that two optoelectronic dies 44 and 44a are located on the header 12 or 22. One of the optoelectronic dies 44 and 44a is a LED (or laser diode), and the other one of the optoelectronic dies 44 and 44a is a photo detector. The transimpedance amplifier 77, the postamplifier 78 and the driver 79 may be integrated as an specific IC, which is located on the header 12 and electrically connected to two optoelectronic dies 44 and 44a.

In this embodiment, it is mentioned that the photo detector 70 has the P-side Up package type. After the photo detector 70 is fixed, two electrodes 73 and 74 are exposed to serve as the wire bonding regions. As mentioned hereinabove, the property of the optoelectronic component may be enhanced without the need of the submount. In addition, no submount is provided in the optoelectronic device, so the manufacturing cost can be significantly reduced. The light rays may be emitted and received, and different package types of the P-side down and the P-side up packages may be satisfied by selecting the proper adhesive layer material and using optoelectronic die with the proper architecture.

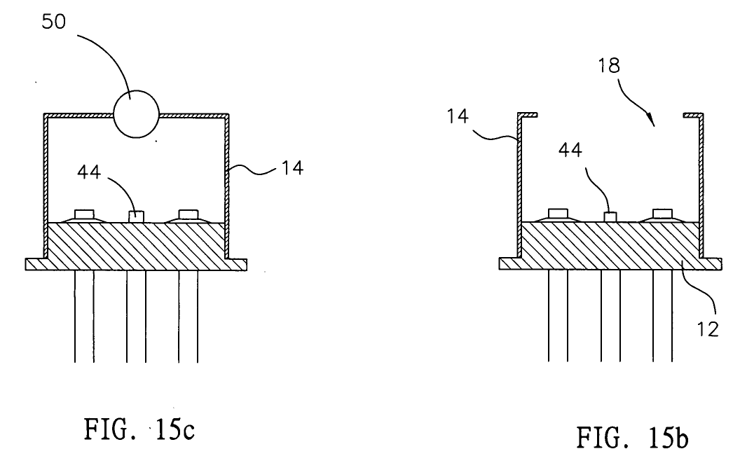

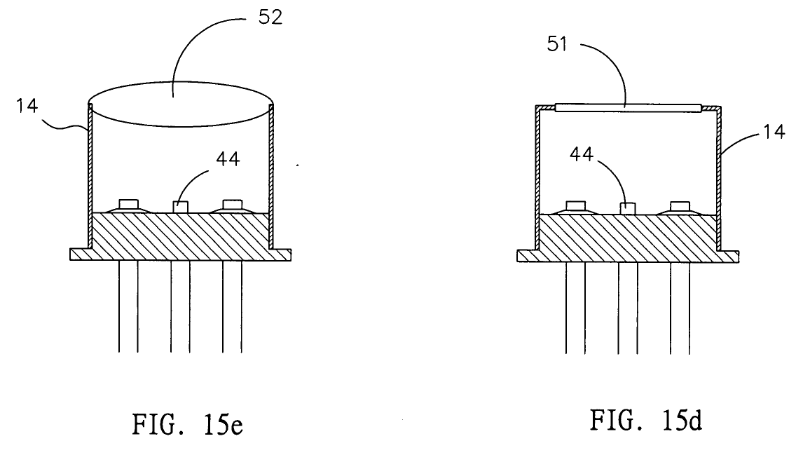

FIG. 15a shows that the optoelectronic die 44 is adhered to the header 12, wherein no housing is located on the header 12. The surface of the optoelectronic die 44 may be exposed or may be covered by a film.

In addition, the combined architecture of the optoelectronic device and the metal housing 14 will be described in the following. The surface of the optoelectronic die 44 is not covered by the thin film 48. However, the structure, in which the surface of the optoelectronic die 44 is covered by the film 48, is still the same as that described hereinbelow.

FIG. 15b shows the header 12 being a TO-can header, wherein a housing 14 is located on the header 12, and an opening 18 is formed at one end of the housing 14 and located opposite the optoelectronic die 44.

FIG. 15c shows a ball lens 50 located at one end of the housing 14 and opposite the optoelectronic die 44. FIG. 15d shows that a piece of flat window 51 is located on the housing 14 and opposite the optoelectronic die 44. FIG. 15e shows a lens structure 52, such as an epoxy lens, located at one end of the housing 14 and opposite the optoelectronic die 44.

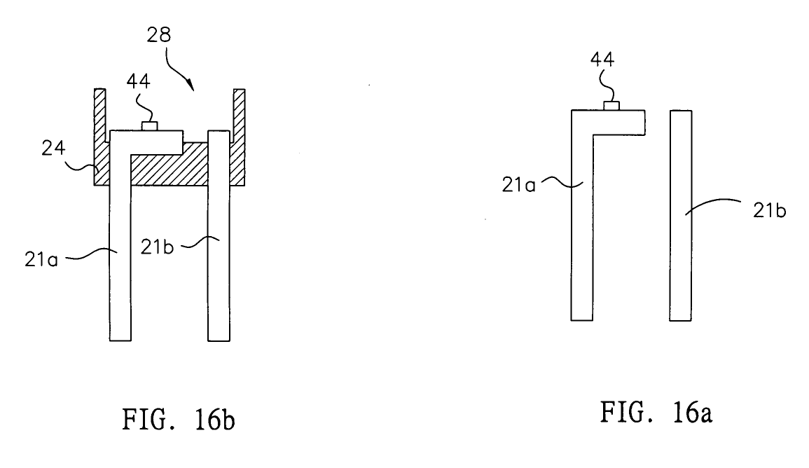

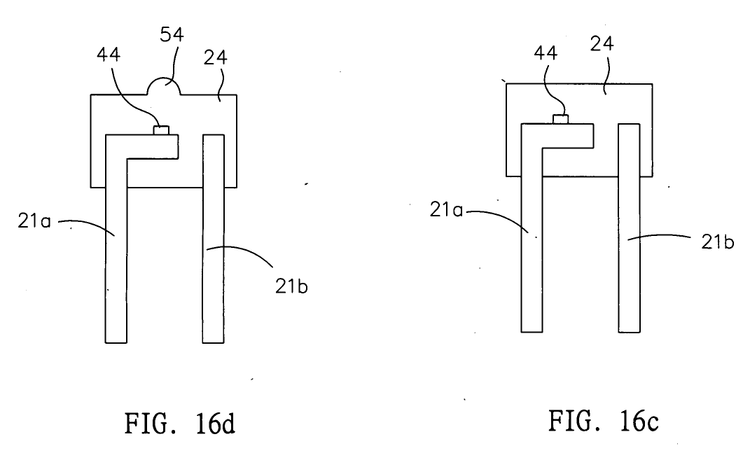

FIG. 16a shows the optoelectronic device without the submount, wherein its optoelectronic die 44 is adhered to one end of one frame 21 of the leadframe architecture. Based on the direction in the drawing, no housing or package body is located at first ends of two leads 21a and 21b. Also, the surface of the optoelectronic die 44 may be exposed or covered by a film (not shown).

The combined architecture of the optoelectronic device and the resin housing 24 without the submount will be described in the following. The surface of the optoelectronic die 44 may not be covered by the thin film 48. However, the structure, in which the surface of the optoelectronic die 44 is covered by the thin film 48, is still the same as that mentioned hereinbelow.

FIG. 16b shows a housing 24 formed at the end portions of the leads 21a and 21b, wherein an opening 28 is formed on the housing 24 and located opposite the optoelectronic die 44. FIG. 16c shows that the housing 24 with the closed structure is located at first ends of the leads 21a and 21b. FIG. 16d shows that the housing 24 with the closed structure is located at first ends of the leads 21a and 21b, and a lens 54 is formed on the housing 24 and located opposite the optoelectronic die 44.

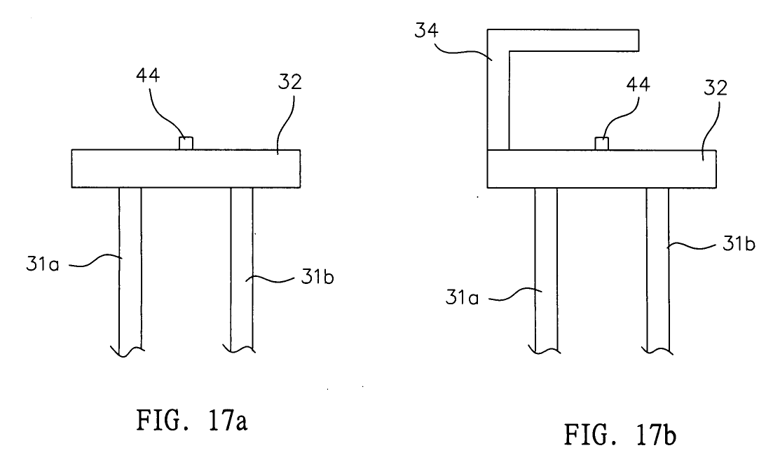

FIG. 17a shows that the optoelectronic die 44 is adhered to the header 32 and that no housing is located around the optoelectronic die 44. The header 32 may be a plastic headerplate or metal headerplate. Taking the plastic material as an example, the header 32 is formed on the frames 31a and 31b by way of injection molding. The optoelectronic die 44 is adhered to the header 32 and electrically connected to the frame 31a.

FIG. 17b shows that a housing 34 is located on the header 32. More particularly, the housing 34 and the header 32 are formed on the leads 31a and 31b by way of injection molding. The optoelectronic die 44 may be an edge emitting component or a surface-emitting component.

The surface of the optoelectronic die 44 in each of FIGS. 17a and 17b may be covered by a thin film 48 or may be exposed.

The matching component 46 located in the optoelectronic device 16, 26 or 36 may be a transimpedance amplifier, a postamplifier, a driver integrated circuit, a passive device (e.g., resistor, capacitor or inductor), an active device (e.g., Zener diode) located on the header or any combination thereof. The passive or active device provides at least one of the anti-surge function, voltage transforming function, rectifying function, voltage regulating function, sensing function, feedback circuit function and impedance matching function.

Also, the optoelectronic die 44 may be a LED or a LD for emitting light rays; or may be a photo detector (or photodiode, hereinafter referred to as PD) for receiving light rays. The optoelectronic die 44 is applied to the optical fiber communication of the glass optical fiber, which emits or receives the infrared optical signal with the wavelength ranging from 800 nm to 1800 nm. When the optoelectronic die 44 is applied to the optical fiber communication with the plastic optical fiber, it emits or receives the visible light optical signals having the wavelength ranging from 200 nm to 800 nm.

Also, the film 48 is made of a material, such as a polymeric material or adhesive, with the low viscosity coefficient lower than 5000 cps (like Karo Syrup). Alternatively, the film 48 may be made of the material having a viscosity coefficient lower than 100 cps, but in some cases higher than 1 cps (water). After the material properly volatilizes, the film is ultra thin, and typically has thickness of less than 2 micrometers and preferably less than 1 micrometer over the major portion of covered surface, and tends to have the uniform conformal coating effect, which is advantageous to the optoelectronic die 44 in resisting the component property deterioration caused by the high temperature and the high humidity environment. In addition, the optical property variations of the optoelectronic devices 16, 26 and 36 may be reduced. In other words, covering the film 48 over the optoelectronic die 44 and/or the surface of the matching component 46 is advantageous to the improvement of the component reliability.

The polymeric material of the film 48 is preferably a fluoro-polymer having the corresponding solvent of methoxy-nonafluorobutane with the molecular formula of C₄F₉OCH₃. The fluoro-polymer may be one of a fluorochemical acrylate polymer, a fluorosilane polymer, a fluoroaliphatic polymer, a methyl nonafluoroisobutyl ether, a methyl nonafluorobutyl ether and other similar materials, or any combination thereof. The selected solvent needs to have the low boiling point (lower than 65° C. is preferred), and after its mixed solution covers the component and properly volatilizes to form a dry film, the surface energy of the dry film ranges from 10 to 15 dynes/cm. Under a predetermined condition, the thickness of the volatilized film may be reduced to around 1 micrometer, even to 0.1, 0.01 micrometer or less, depending on the application environment. In some cases, the film still has the effect of preventing the component from deteriorating, especially in the damp heat environment.

In one method of covering the polymeric material over the optoelectronic die, a semiconductor optoelectronic die is immersed in a dilute polymeric material, and then the optoelectronic die is taken out to dry the polymeric material. The dip coating could be done at room temperature without oven curing. Consequently, the dried polymeric material may be formed into a polymeric film covering the surface of the optoelectronic die.

In another method of covering the polymeric material over the optoelectronic die, the polymeric material is dropped into the chamber through the cup-like container formed by the opening of the housing of the optoelectronic component so that the polymeric material can cover the surface of the optoelectronic die and/or the surface of the matching component. After the polymeric material properly volatilizes, a film is formed to cover the surface of the optoelectronic die and/or the surface of the matching component. Sometimes, the film only covers the surface of the matching component but does not completely cover the optoelectronic die to protect the fragile III-V component, e.g., GaAs or InP chip/IC to reduce the influence of the optical and/or electrical property of the optoelectronic die.

The architecture of the optical sub-assembly is the combination of one optoelectronic component and one barrel. The architecture of the optoelectronic component has been mentioned hereinabove. The architecture of the barrel will be described in the following.

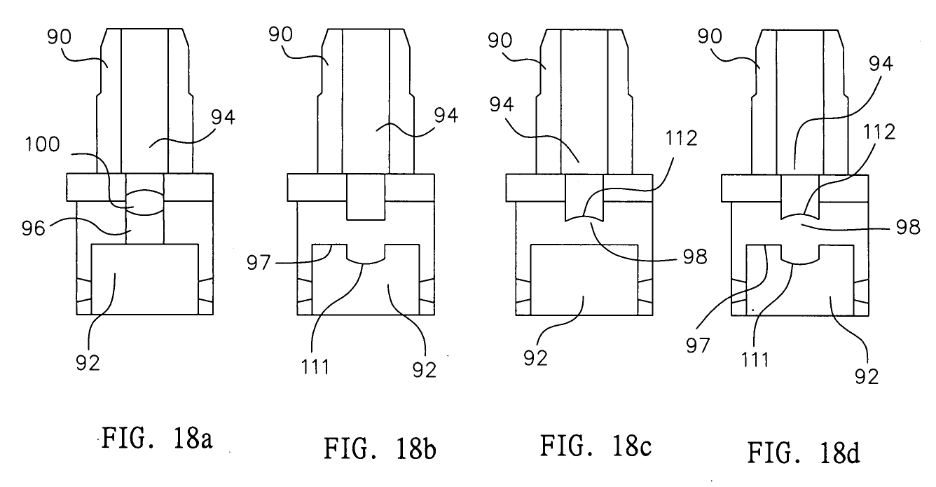

FIGS. 18a to 18d show four examples of the various barrels 90 each having a chamber 92 and an optical fiber channel 94.

As shown in FIG. 18a, an accommodating channel 96 is located between the barrel chamber 92 and the optical fiber channel 94 of the barrel 90, and at least one lens 100 may be located in the accommodating channel 96.

As shown in FIG. 18b, an end surface of the barrel chamber 92 is a first surface 97, and a first lens 111 is formed on the first surface 97.

As shown in FIG. 18c, the bottom of the optical fiber channel 94 has a second surface 98, and a second lens 112 is formed on the second surface 98.

As shown in FIG. 18d, a first lens 111 is formed on the first surface 97 of the chamber 92, and the second surface 98 of the optical fiber channel 94 is formed with a second lens 112 located opposite the first lens 111.

It is to be noted that any one of the barrels 90 of FIGS. 18a to 18d can be a unit either by single plastic injection molding or by combining metal receptacle and plastic/glass lens/lenses, wherein a flat window surface can also be treated as a lens with an unlimited radius of curvature. Each may be combined with the optoelectronic component 10, or 30 so that the optical sub-assembly for optical communication may be formed and may be mounted on the signal transmitting end or the signal receiving end of the optical fiber according to the requirement. It is also noted that the first and second surface are preferably closed surfaces.

The details of the architecture of the optical sub-assembly will be described in the following.

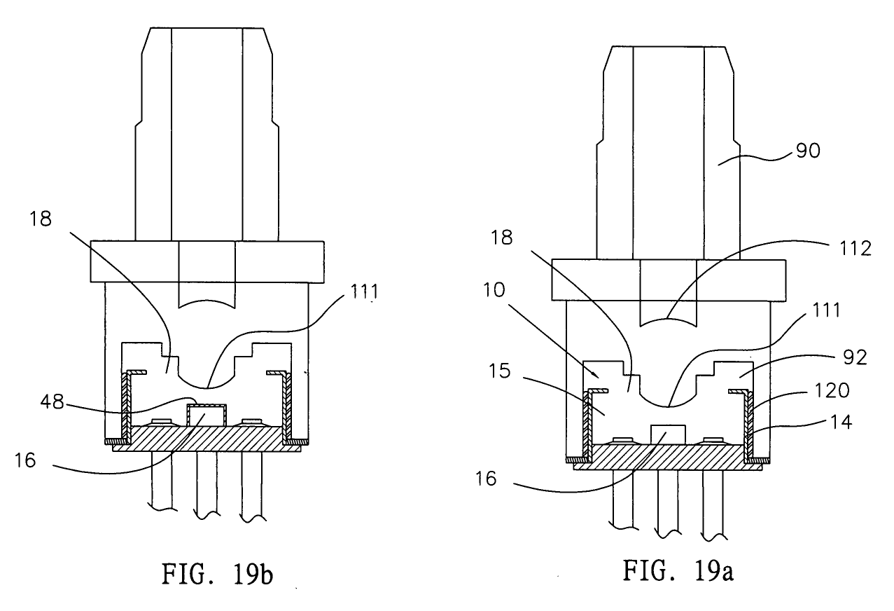

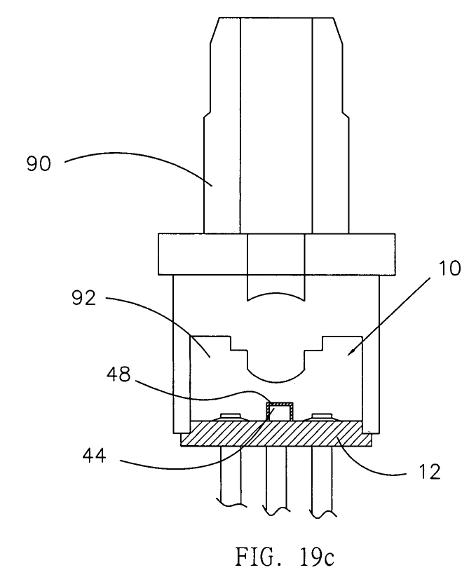

FIG. 19a shows that the optoelectronic component 10 with the TO-can architecture is combined with a barrel 90 to form an optical sub-assembly. The barrel 90 has the first lens 111 and the second lens 112. The housing 14 of the optoelectronic component 10 is inserted into the barrel chamber 92, and an adhesive agent 120 adheres the external side surface of the housing 14 to the inner wall surface of the barrel chamber 92 so that the space constituted by the barrel chamber 92 and the housing chamber 15 of the housing 14 is preferably in a hermetically-sealed status. The sealed space structure can prevent the optoelectronic device 16 from being influenced by the external environment. Furthermore, the airtight space can be vacuumed or filled with a stable gas, like Nitrogen.

Also, the first lens 111 is located opposite the optoelectronic device 16, so the optical coupling effect between the optoelectronic device 16 and the first lens 111 may be increased by extending the first lens 111 toward the optoelectronic device 16, especially by extending the first lens 111 through the opening 18.

FIG. 19b shows that the thin film 48 may cover the surface of the optoelectronic device 16. The covering region of the thin film 48 includes a portion of or a whole surface of the optoelectronic device 16. In addition, the first lens 111 may penetrate through the opening 18 and thus further approach the optoelectronic device 16 with an optimized result of the efficiency so that the optical coupling effect between the optoelectronic device 16 and the first lens 111 may be enhanced.

FIG. 19c shows the optoelectronic component (shown as FIG. 11b) is combined with a barrel 90 to form an optical subassembly, wherein the optoelectronic die 44 of the optoelectronic component 10 is fixed on the header 12, and the thin film 48 is covered on the optoelectronic die 44. The barrel chamber 92 is preferably in a hermetically-sealed status, which is not a must under the thin film covered. The same concept could be applied to To-can embodiment, which comprises an optoelectronic die fixed on the header (a submount, a matching component or both may be interposed between), and a housing with an optical element combined with the header.

According to the teachings mentioned hereinabove, the optoelectronic component may have the TO-can architecture as well as the leadframe architecture. In addition, the thin film 48 may cover the optoelectronic die 44 or may be omitted.

The optoelectronic component may be any optoelectronic component mentioned in this specification, and the optoelectronic device further includes an optoelectronic die located on the matching component, or an optoelectronic die located on the submount. Alternatively, the optoelectronic die may be adhered to the header without the submount structure, and the portion of the lens is not restricted to whether the integrally formed member is formed or whether the lens is mounted thereafter.

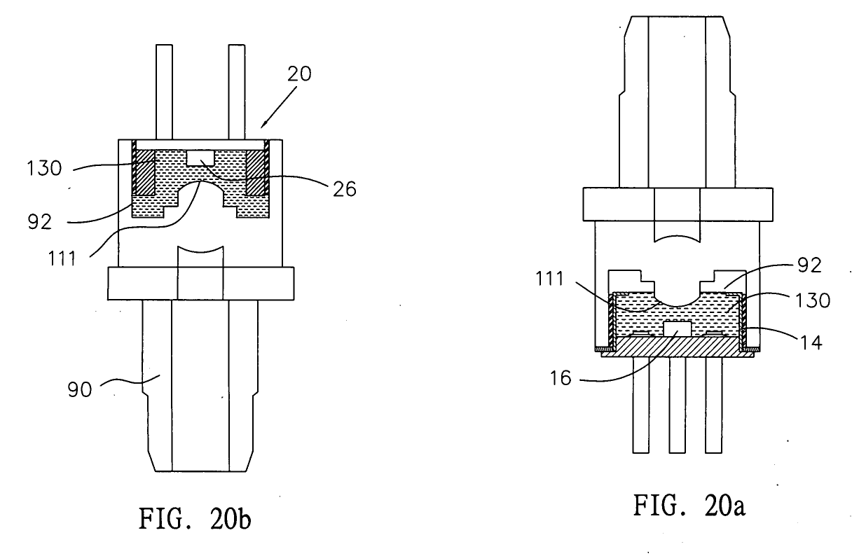

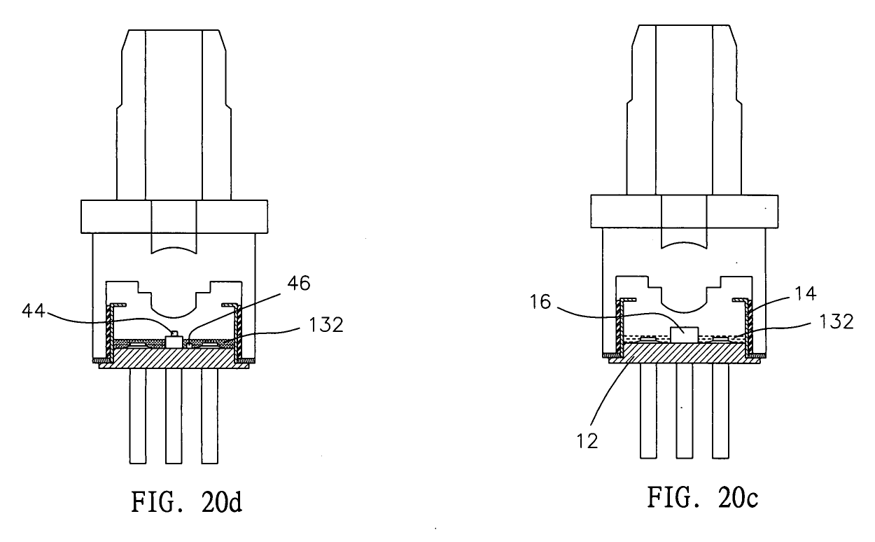

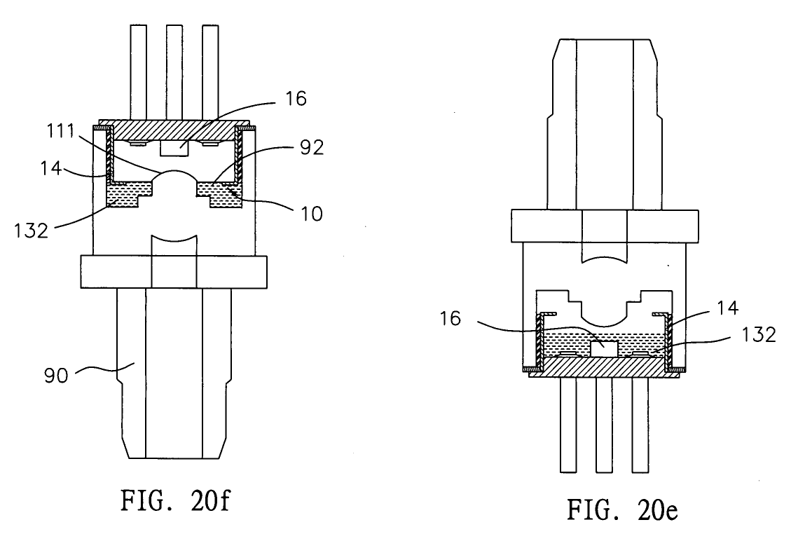

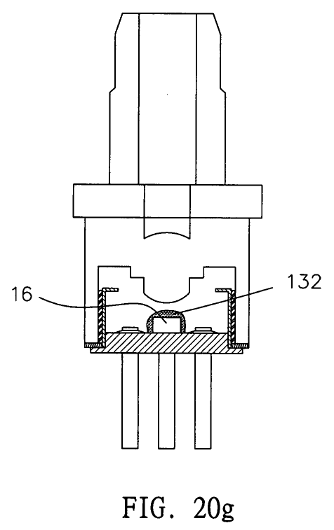

In addition, FIG. 20a shows an embodiment, in which the optoelectronic component with the TO-can architecture is combined with the barrel. In this embodiment, an index matching oil 130 is provided to fill the internal space of the housing 14 and/or the barrel chamber 92. Thus, a smaller diverging angle may be obtained when the optical signal travels between the optoelectronic device 16 and the first lens 111 so that the optical coupling effect can be enhanced, and the effect of protecting the optoelectronic device 16 may be obtained. The index matching oil 130 may be replaced with a glue having the fixing and protecting properties.

FIG. 20b shows an embodiment, in which the optoelectronic component with the leadframe architecture is combined with the barrel. In this embodiment, the index matching oil 130 is filled into the barrel chamber 92, and then the optoelectronic component 20 is inserted into the barrel chamber 92 so that the optoelectronic component 20 is combined with the barrel 90. Thus, a smaller diverging angle may be obtained to enhance the optical coupling effect when the optical signal travels between the optoelectronic device 26 and the first lens 111. In addition, the index matching oil 130 also has the effect of protecting the optoelectronic device 26.

FIG. 20c shows that the optoelectronic component with the TO-can architecture is combined with the barrel. In this embodiment, a glue 132 with the fixing and protecting properties is filled into the housing 14, and the filling height of the glue 132 ranges between the top surface of the optoelectronic device 16 and the top surface of the header 12 to form the structure pattern of partially covering the optoelectronic device 16. Thus, the effects of protecting the adhesive material and the optoelectronic device 16 may be obtained.

FIG. 20d shows that the glue 132 partially covers the optoelectronic device 16. The glue 132 further completely covers the top surface of the matching component 46 (e.g., transimpedance amplifier, postamplifier, driver integrated circuit, passive device or active device) and does not cover the top surface of the optoelectronic die 44.

FIG. 20e shows that the glue 132 is filled into the internal space of the housing 14, and the filling height of the glue 132 exceeds the top surface of the optoelectronic device 16 to complete cover the optoelectronic device 16. Thus, the effects of protecting the adhesive material and the optoelectronic device 16 may be obtained.

FIG. 20f shows that the glue 132 is filled in the barrel chamber 92 of the barrel 90 and does not flow over the first lens 111. When the optoelectronic component 10 is inserted into the barrel chamber 92, the glue 132 is adhered to the end portion of the housing 14 so that the housing 14 is preferably hermetically-sealed and the glue 132 does not contact the optoelectronic device 16.

FIG. 20g shows that the glue 132 is coated on the optoelectronic device 16, and that the glue 132 completely or partially covers the optoelectronic device 16.

In the optical sub-assembly of the invention, the first lens may penetrate through the opening to approach the optoelectronic device. Consequently, the optoelectronic device may not have the submount, and the first lens still can approach the optoelectronic die. So, the optical coupling efficiency can be optimized. In addition, using the index matching oil can converge the diverging angle of the light and achieve the effect of increasing the optical coupling efficiency. Also, filling the index matching oil or glue can achieve the effect of protecting the optoelectronic component. In addition, the optoelectronic component, especially the optoelectronic component with the TO-can architecture, has the lowered manufacturing cost because the metal housing has no glass piece or spherical lens. Thus, the low-cost advantage is still obtained after the optical sub-assembly is formed.

However, when the glue 132 is made of the epoxy, silicone, urethane or acrylic material, the thick film having the thickness greater than several tens of micrometers tends to be formed, and the glue or the index matching oil may generate bubbles and the inconsistent curvatures, especially in mass production. Nevertheless, the use of the glue or the index matching oil can protect the material and enhance the optical coupling at the expense of manufacturability. However, if the polymeric material (e.g., the fluoro-polymer) of the embodiment having the low viscosity coefficient is coated on the surface of the optoelectronic die and naturally volatilizes, the influence factors mentioned hereinabove may be improved with respect to the optoelectronic component, and the consistency of the property of the optoelectronic component may further be enhanced.

Next, in the embodiment wherein the thickness of the film is preferably less than 1 micrometers, the thickness is directed to the thickness of the film of most of the region above the active region of the optoelectronic die. Usually, the thickness of the film in the vicinity of the wire or on the other corners may be locally increased without affecting optical property and deviating from the equivalent scope of the invention.

Furthermore, types of barrel structures, the TO-can or the leadframe architecture with an opening or any kind of optical element, the matching component, the optoelectronic device having the submount or not, the coating of the material with a low viscosity coefficient or not (including the coating method, the thickness selection or the material selection), the sealed condition of the chamber formed in the barrel and the housing or not, or the stacked and arranged manner of the optoelectronic die and the matching component may be modified according to various kinds of market requirements. Herein, only several embodiments are illustrated, and any combination or slight modification may still fall within the scope of the invention.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. An optical sub-assembly, comprising:
a barrel having a barrel chamber and an optical fiber channel, wherein one end of the barrel chamber is a first surface, and one end of the optical fiber channel is a second surface;
an optoelectronic component having a housing and inserted into the barrel chamber of the barrel, wherein an opening is formed at one end of the housing, and an optoelectronic device is located inside the housing and opposite the opening; and
at least one lens located between the optical fiber channel and the optoelectronic device and opposite the optoelectronic device;
wherein the optoelectronic device is covered by a thin film with a low viscosity coefficient.

2. The optical sub-assembly according to claim 1, wherein the first surface and/or second surface are closed.

3. The optical sub-assembly according to claim 1, wherein the film is a polymeric film.

4. The optical sub-assembly according to claim 1, wherein the viscosity coefficient of the thin film is lower than 100 cps.

5. The optical sub-assembly according to claim 1, wherein thickness of the thin film is less than 1 micrometer.

6. The optical sub-assembly according to claim 3, wherein the composition/compositions of the polymeric film comprises/comprise a fluoro-polymer.

7. The optical sub-assembly according to claim 6, wherein the fluoro-polymer is selected from at least one of the group consisting of a fluorochemical acrylate polymer, a fluorosilane polymer, a fluoroaliphatic polymer, a methyl nonafluoroisobutyl ether and a methyl nonafluorobutyl ether.

8. The optical sub-assembly according to claim 1, wherein surface energy of the thin film ranges from 10 to 15 dynes/cm.

9. The optical sub-assembly according to claim 1, wherein an interposed chamber formed by the housing of the optoelectronic component and the barrel chamber of the barrel is in a hermetically-sealed status.

10. The optical sub-assembly according to claim 1, wherein there is one lens formed on the first surface or the second surface, and the lens is located opposite the optoelectronic device.

11. The optical sub-assembly according to claim 10, wherein the lens is located on the first surface and extends through the opening of the housing to approach the optoelectronic device.

12. The optical sub-assembly according to claim 1, wherein there are two lenses comprising a first lens and a second lens, the first lens is formed on the first surface, and the second lens is formed on the second surface.

13. The optical sub-assembly according to claim 12, wherein the first lens extends through the opening of the housing to approach the optoelectronic device.

14. The optical sub-assembly according to claim 9, wherein the interposed chamber is vacuumed or filled with a stable gas.

15. The optical sub-assembly according to claim 1, wherein the optoelectronic device comprises an optoelectronic die, and the thin film covers an active region of the optoelectronic die.

16. The optical sub-assembly according to claim 1, wherein the optoelectronic device comprises an optoelectronic die and a matching component(s) electrically connected to the optoelectronic die.

17. The optical sub-assembly according to claim 16, wherein the optoelectronic device further comprises a submount, and the optoelectronic die is located on the submount and electrically connected to the matching component(s).

18. The optical sub-assembly according to claim 17, wherein the thin film covers a surface of the matching component(s).

19. The optical sub-assembly according to claim 1, wherein the optoelectronic device comprises at least one optoelectronic die, which is a photo detector (PD) die, a light-emitting diode (LED) die, a laser diode (LD) die, or any combination thereof.

20. The optical sub-assembly according to claim 1, wherein the optoelectronic device comprises a matching component(s), which is an active device, a passive device, a transimpedance amplifier, a postamplifier, a driver integrated circuit, or any combination thereof.

21. An optoelectronic component, comprising:
a header;
a housing having a housing chamber and located on the header;
an opening formed at one end of the housing and communicating with the housing chamber;
an optoelectronic device located in the housing chamber, fixed to the header, and located opposite the opening; and
a thin film, made of a material with a low viscosity coefficient, for covering a surface of the optoelectronic device.

22. The optoelectronic component according to claim 21, wherein the thin film is a polymeric film.

23. The optoelectronic component according to claim 21, wherein the viscosity coefficient of the thin film is lower than 100 cps.

24. The optoelectronic component according to claim 21, wherein a thickness of the thin film is less than 1 micrometer.

25. The optoelectronic component according to claim 21, wherein the optoelectronic device has an optoelectronic die, and the film covers an active region of the optoelectronic die.

26. The optoelectronic component according to claim 21, further comprising an optical element is located at the opening.

27. The optoelectronic component according to claim 26, wherein the optical element is a ball lens, a flat window, an aspherical lens, an epoxy-lens, or an injection-molding-lens.

28. The optoelectronic component according to claim 26, wherein the housing chamber is in a hermetically-sealed status.

29. An optical sub-assembly, comprising:
a barrel having a barrel chamber;
an optoelectronic component combined with the barrel, wherein the optoelectronic component has a header and an optoelectronic device, and the optoelectronic device is fixed to the header; and
a thin film, made of a material with a low viscosity coefficient, for covering a surface of the optoelectronic device.

30. The optical sub-assembly according to claim 29, further comprising a housing having a housing chamber and located on the header, wherein the optoelectronic device is located in the housing.

31. The optical sub-assembly according to claim 30, further comprising an optical element located at one end of the housing and opposite the optoelectronic device.

32. The optical sub-assembly according to claim 29, wherein the thin film is a polymeric film.

33. The optical sub-assembly according to claim 29, wherein the viscosity coefficient of the thin film is lower than 100 cps.

34. The optical sub-assembly according to claim 29, wherein thickness of the thin film is less than 1 micrometer.

35. The optical sub-assembly according to claim 29, wherein the optoelectronic device has an optoelectronic die, and the thin film covers an active region of the optoelectronic die.

36. The optical sub-assembly according to claim 31, wherein the optical element is a ball lens, a flat window, an aspherical lens, an epoxy-lens, or an injection-molding-lens.

37. The optical sub-assembly according to claim 31, wherein the optical element is a piece of light-converging device.

38. The optical sub-assembly according to claim 29, wherein the barrel chamber is in a hermetically-sealed status.

39. The optical sub-assembly according to claim 38, wherein the leak rate of the hermetically-sealed status is lower than 5×10⁻⁵ atm-cc/sec.

40. The optical sub-assembly according to claim 30, wherein the housing chamber is in a hermetically-sealed status.

41. The optical sub-assembly according to claim 29, further comprising a housing having a housing chamber, an opening is formed at one end of the housing and communicating with the housing chamber.

42. The optical sub-assembly according to claim 29, wherein surface energy of the thin film ranges from 10 to 15 dynes/cm.

43. The optical sub-assembly according to claim 29, wherein the optoelectronic device has an optoelectronic die, and the optoelectronic die is fixed on the header without any submount.
